(19) United States
(12) Patent Application Publication
(10) Pub. No.: US 2019/0326114 A1
(43) Pub. Date: Oct. 24, 2019

(54) METHODS OF TREATING A SUBSTRATE TO FORM A LAYER THEREON FOR APPLICATION IN SELECTIVE DEPOSITION PROCESSES

(71) Applicant: APPLIED MATERIALS, INC., Santa Clara, CA (US)

(72) Inventors: JESSICA S. KACHIAN, SUNNYVALE, CA (US); JUKKA TANSKANEN, HELSINKI (FI); WENYU ZHANG, San Jose, CA (US); MICHAEL S. JACKSON, SUNNYVALE, CA (US); CHANG KE, SUNNYVALE, CA (US); LIQI WU, SANTA CLARA, CA (US)

(21) Appl. No.: 16/381,755

(22) Filed: Apr. 11, 2019

Related U.S. Application Data
(60) Provisional application No. 62/689,216, filed on Jun. 24, 2018.
(60) Provisional application No. 62/660,098, filed on Apr. 19, 2018.

(51) Int. Cl. H01L 21/02; C23C 16/458

(52) U.S. Cl. CPC H01L 21/02636; C23C 16/4586

(57) ABSTRACT

Methods for treating a substrate including: contacting a substrate having a top surface with a first self-assembled monolayer (SAM) precursor or a first small-molecule monolayer (SMM) precursor, a co-reactant, and a second SAM precursor or a second SMM precursor to form a first layer on the top surface. Selective deposition methods are also disclosed.

### CROSS-REFERENCE TO RELATED APPLICATIONS

This application claims benefit of U.S. provisional patent application Ser. No. 62/689,216, filed Jun. 24, 2018 and U.S. provisional patent application Ser. No. 62/660,098, filed Apr. 19, 2018 which are both herein incorporated by reference in their entireties.

### FIELD

Embodiments of the present disclosure generally relate to methods for the fabrication of semiconductor devices in which a self-assembled monolayer is used to achieve selective area deposition including, for example, a method of treating a substrate to form a layer thereon suitable for application in selective deposition processes and methods of depositing a film selectively onto a substrate, such as a substrate having a first surface and a second surface.

### BACKGROUND

Selective deposition processes are gaining a lot of momentum mostly because of the need for patterning applications for semiconductors. Traditionally, patterning in the microelectronics industry has been accomplished using various lithography and etch processes. However, since lithography is becoming exponentially complex and expensive the use of selective deposition to deposit features is becoming much more attractive. Another potential application for selective deposition is gap fill. In gap fill, the fill film is grown selectively from the bottom of a trench towards the top. Selective deposition could be used for other applications such as selective sidewall deposition where films are grown on the side of a fin. Such selective sidewall deposition would enable the deposition of a sidewall spacer without the need for complex patterning steps.

Therefore, there is a need for improved SAM formation methods and the inventors have provided improved methods of treating a substrate to form a layer thereon and improved methods of depositing a film selectively onto a substrate. Moreover, the inventors have provided improved methods for treating substrate by contacting substrate (or set of substrates) with a first surface and a second surface with reactant(s) to form a first layer on the second surface; depositing a film on the first surface selectively over the second surface; and removing the first layer from the second surface.

### SUMMARY

Methods for treating a substrate and selective deposition are provided herein including treating a substrate having a first surface and a second surface by contacting the substrate (or set of substrates) with reactants to form a first layer on the second surface; depositing a film on the first surface selectively over the second surface; and removing the first layer from the second surface.

In some embodiments, a method of treating a substrate includes: contacting a substrate having a top surface or outer surface with a first self-assembled monolayer (SAM) precursor or a first small-molecule monolayer (SMM) precursor, a co-reactant, and a second SAM precursor or a second SMM precursor to form a first layer on the top surface or outer surface.

In some embodiments, a selective deposition method includes: contacting a substrate with a first surface and a second surface with a self-assembled monolayer (SAM) precursor or a first small-molecule monolayer (SMM) precursor, a co-reactant, and a second SAM precursor or a second SMM precursor to form a first layer on the second surface; depositing a film on the first surface selectively over the second surface; and removing the first layer from the second surface.

In some embodiments, a selective deposition method includes: (a) contacting a substrate with a first surface and a second surface with a first SAM precursor or a first SMM precursor; (b) subsequently, contacting a substrate with a first surface and a second surface with a co-reactant; (c) subsequently, contacting a substrate with the first surface and the second surface with a second SMM precursor or a second SAM precursor to form a layer on the second surface; and optionally repeating (a), (b) and (c) until the layer has a desired surface coverage of the second surface. In some embodiments, a desired surface coverage includes coverage sufficient to form a blocking layer on the second surface. In embodiments, a desired surface coverage includes maximizing surface coverage of a blocking layer, or creating a blocking layer without a substantial number of reactive sites, or no reactive sites on the surface of the substrate.

In some embodiments, a method of treating a substrate includes: (a) contacting a substrate having a top surface or outer surface with a first small-molecule monolayer (SMM) precursor; and (b) contacting the first small-molecule monolayer (SMM) precursor with a co-reactant, and repeating (a), (b) until a layer having a desired surface coverage is formed thereon. In one such embodiment, the first small-molecule monolayer (SMM) precursor has two or three (several) reactive head groups.

In some embodiments, a method of treating a substrate includes: (a) contacting a substrate having a top surface or outer surface with a first self-assembled monolayer (SAM) precursor, wherein the first SAM precursor has a tail group having a first length; (b) contacting the first SAM precursor with a co-reactant; (c) contacting the substrate with a second self-assembled monolayer (SAM) precursor, wherein the second SAM precursor has a tail group having a second length shorter than the first length, and repeating (a), (b), and (c) until a SAM layer having a desired surface coverage is formed thereon.

In some embodiments, the present disclosure relates to a non-transitory computer readable medium having instructions stored thereon that, when executed, cause a method of treating a substrate in a process chamber, including: contacting a substrate having a top surface with a first self-assembled monolayer (SAM) precursor or a first small-molecule monolayer (SMM) precursor, a co-reactant, and a second SAM precursor or a second SMM precursor to form a first layer on the top surface.

In some embodiments, the present disclosure relates to a non-transitory computer readable medium having instructions stored thereon that, when executed, cause a method of treating a substrate in a process chamber, including: contacting a substrate with a first surface and a second surface with a first self-assembled monolayer (SAM) precursor or a first small-molecule monolayer (SMM) precursor, a co-reactant, and a second SAM precursor or a second SMM precursor to form a first layer on the second surface; depositing a film on the first surface selectively over the second surface; and removing the first layer from the second surface.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate typical embodiments of the disclosure and are therefore not to be considered limiting of scope, for the disclosure may admit to other equally effective embodiments.

FIG. 1 depicts a flow chart of a method of treating a substrate in accordance with some embodiments of the present disclosure.

FIGS. 2A-2C depict side cross-sectional views of substrate treated in accordance with the present disclosure

FIG. 3 is a deposition chamber suitable to perform methods accordance with the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The following disclosure describes processes for the fabrication of semiconductor devices in which a self-assembled monolayer is used to achieve selective deposition. For example, in embodiments, methods of treating a substrate to form a layer thereon and methods of depositing a SAM layer or film selectively onto a substrate are provided herein. The methods of the present disclosure are advantageous in that the inventors have observed the treatment and selective deposition methods of the present disclosure improve integrated circuit (IC) processing by replacing lithography steps with alternatives that translate to one or more of lower cost, reduced processing time, and smaller feature sizes. Further, preselecting SAM precursors and sequential application of the preselected SAM precursors enhances surface coverage of a substrate by eliminating voids or pinholes in a SAM layer formed atop a substrate that may be detrimental to the deposition of subsequent material thereon. Moreover, preselecting SAM precursors and sequential deposition of different preselected SAM precursors as described below facilities formation of a densely packed SAM layers improving coverage of the substrate by reducing or eliminating voids in the deposited layer. Moreover, with respect to SMM precursors, the inventors have observed that the delivery of one or more SMM precursors is easier than SAM precursor delivery and may reduce problems associated with condensation/physisorption. Moreover, application of a SAM precursor having a shorter tail group after applications of a SAM precursor with a long tail group (when compared to the short tail group) mitigates droplet defect problems on the substrate surface.

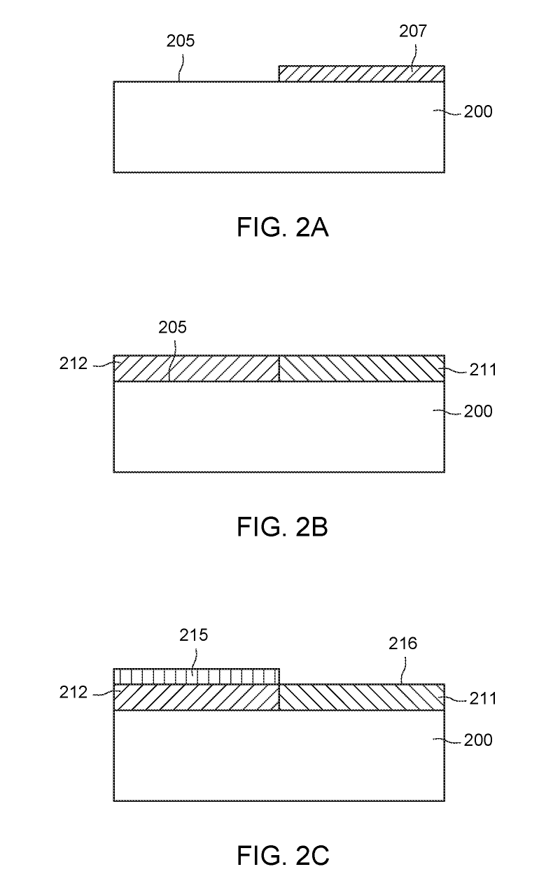

In embodiments, a method of processing a substrate (such as substrate 200 in FIG. 2) is provided. For example, embodiments of the disclosure include exposing or treating a substrate to form a layer such as a self-assembled monolayer (SAM), small-molecule monolayer (SMM), or combinations thereof atop the substrate. In embodiments, suitable substrate for use in accordance with the present disclosure may be a semiconductor wafer as known in the art, or may include a surface, or portion of a surface, upon which a process acts. In embodiments, a substrate may be any substrate or material surface formed on a substrate upon which film processing is performed during a fabrication process. In embodiments, a substrate comprises at least an exposed first material and an exposed second material. In one embodiment, the substrate may comprise a material such as crystalline silicon (e.g., Si<100> or Si<111>), silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, and combinations thereof. In embodiments, the substrate may have various dimensions, such as 200 mm, 300 mm, 450 mm or other diameters for round substrates. The substrate may also be any polygonal, square, rectangular, curved or otherwise non-circular workpiece, such as a polygonal glass substrate used in the fabrication of flat panel displays. Unless otherwise noted, implementations and examples described herein are conducted on substrates with a 200 mm diameter, a 300 mm diameter, or a 450 mm diameter substrate.

In some embodiments, the substrate may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, film processing disclosed herein may also be performed on an underlayer formed on the substrate. Thus for example, where a film/layer or partial film/layer has been deposited onto a substrate surface, the exposed surface of the newly deposited film/layer becomes the substrate surface. In some embodiments, a first substrate surface may include a metal, metal oxide, or H-terminated SiₓGe₁₋ₓ, and a second substrate surface may comprise a Si-containing dielectric, or vice versa. In some embodiments, a substrate surface may comprise certain functionality (e.g., —OH, —NH, etc.). In embodiments, and in preparation for deposition of a SAM layer or film, the substrate may be exposed to an optional pre-clean process prior to the SAM layer or film formation process. The pre-clean process may be any pre-clean process capable of removing native oxides, contaminants, or both from the exposed surfaces. The pre-clean process may be a dry chemical clean process, a wet chemical clean process, or both. The pre-clean process may be a remote plasma clean or an in-situ plasma clean that is adapted to perform a dry etch process. One exemplary dry cleaning process is the SICONI brand pre-clean process available from Applied Materials, Inc., Santa Clara, Calif., which removes native oxide through a low-temperature, two-part dry chemical clean process using NF₃ and NH₃. It is contemplated that other suitably configured cleaning processes from other manufacturers may also be advantageously implemented.

In embodiments, the substrate may include a feature formed from a first material (e.g., a dielectric material). The feature may include, for example, trenches, vias, holes, openings, lines, the like, and combinations thereof. The feature may have an opening that is filled with a second material (e.g., a conductive material) disposed on the substrate. In some embodiments, the first material and the second material may both be dielectric materials. For example, the first material may be a silicon oxide layer and the second material may be a silicon nitride layer.

In embodiments, the substrate may have a top surface or outer surface contacted with one or more precursors such as a reactive gas or vapor including one or more reactant(s) which may include one or more species capable of reacting with the top surface or outer surface of the substrate. For example, a first precursor may adsorb onto the surface of a substrate and be available for further chemical reaction with a second precursor or reactant, or co-reactant.

In embodiments, one or more precursors suitable for use herein includes one or more self-assembled monolayer (“SAM”) precursors suitable for forming a layer of molecules that may attach (e.g., by a chemical bond) to a substrate surface and that have adopted an orientation with respect to that substrate surface and/or with respect to each other. In embodiments, a SAM layer may include an organized layer of amphiphilic molecules in which one end of the molecule, the “head group” shows a specific, reversible affinity for a substrate. Preselection or selection of the head group will depend on the application of the SAM layer, with the type of SAM compounds based on the substrate utilized, and in embodiments, the sequential order in which the SAM precursor(s) contact the substrate. In embodiments, the head group is connected to an alkyl chain or fluorinated alkyl chain in which a tail or “terminal end” can be functionalized, for example, to vary wetting and interfacial properties. In embodiments, preselection or selection of the tail group will depend on the application of the SAM layer, with the type of SAM compounds based on the substrate utilized, and in embodiments, the length of the tail group including the length of the alkyl chain or fluorinated alkyl chain and sequential order in which the SAM precursor(s) contact the substrate. In embodiments, the molecules that form the SAM layer will selectively attach to one material over another material (e.g., metal vs. dielectric) and if of sufficient density, can successfully maintain integrity during subsequent deposition allowing for selective deposition on materials not coated with the SAM layer.

Depending upon the materials used and the SAM precursors used, the SAM precursor may be a solution based precursor or a gaseous precursor. The SAM precursor may comprise one or more SAM molecules, or precursors that form the SAM molecules, or both. In embodiments, the adsorbed SAM precursors or molecules form the SAM layer atop the substrate.

In embodiments, vapor deposition systems are configured to deliver the SAM precursors or molecules at very low pressures (e.g., 0.5 to 2 mTorr) using the vapor pressure of a heated SAM molecule solution to expose the chemistry to the substrate. In embodiments SAM precursors or molecules is applied in an amount sufficient and duration sufficient to form dense high quality SAM layer or film without pinholes or voids. In embodiments, SAM precursors and molecules are preselected to contact a substrate suitable for selective deposition in sequential order, for example preselecting desired number of reactive head groups, preselecting a desired tail group length, or both, as described further below.

In embodiments, the substrate is exposed to one or more SAM precursors to achieve selective adsorption of the one or more SAM precursors on a surface of a first material of a substrate with minimal to no adsorption on the surface of the second material. For example, the substrate may be sufficiently exposed to one or more SAM precursors to achieve selective adsorption of the one or more SAM precursors on a second surface (e.g., of a first material) of a substrate with minimal to no adsorption on the first surface (e.g. a first surface comprising a second material).

In some embodiments, the SAM layer comprises an organized layer of the SAM molecules or precursors, which may be amphiphilic, in which one end of the molecule, a head group shows a specific, reversible affinity for the first material of the substrate or a feature. The head group may be connected to an alkyl chain in which a terminal end can be functionalized. In embodiments, the SAM layer is formed by chemisorption of the head group onto a first material of the substrate or feature, followed by two-dimensional organization of the hydrophobic tail groups. In embodiments of the present disclosure SAM molecules or precursors may be preselected by the number of reactive sites on the head group, and/or length of the tail group comprising an alkyl chain.

In embodiments, suitable SAM molecules which may be utilized in accordance with the implementations described herein include the materials described hereinafter, including combinations, mixtures, and grafts thereof, in addition to other SAM molecules having characteristics suitable for blocking deposition of subsequently deposited materials in a semiconductor fabrication process.

In embodiments, the SAM molecules may be silylamine materials, such as tris(dimethylamino)methylsilane, tris(dimethylamino)ethylsilane, tris(dimethylamino)propylsilane, tris(dimethylamino)butylsilane, tris(dimethylamino)pentylsilane, tris(dimethylamino)hexylsilane, tris(dimethylamino)heptylsilane, tris(dimethylamino)octylsilane, tris(dimethylamino)nonylsilane, tris(dimethylamino)decylsilane, tris(dimethylamino)undecylsilane tris(dimethylamino)dodecylsilane, tris(dimethylamino)tridecylsilane, tris(dimethylamino)tetradecylsilane, tris(dimethylamino)pentadecylsilane, tris(dimethylamino)hexadecylsilane, tris(dimethylamino)heptadecylsilane, tris(dimethylamino)octadecylsilane, and tris(dimethylamino)nonadecylsilane.

In embodiments, the SAM molecules may be chlorosilane materials, such as methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane, and nonadecyltrichlorosilane.

In some embodiments, small-molecule monolayer (SMM) precursors or SAM precursors for use herein include a silicon or Si center. In some embodiments, the Si center may be either 1) bonded to a long inert tail group (linear, saturated hydrocarbon chain containing >3 C atoms), and is a SAM precursor suitable for use in accordance with the present disclosure or 2) bonded to a short inert tail group (saturated hydrocarbon moiety comprised of 1-3 carbon atoms) and may be suitable as an SMM precursor in accordance with the present disclosure. One non-limiting example of a SMM precursor is dimethylaminotrimethylsilane. In embodiments, the first SMM or first SAM (1^{st} blocking precursor), in addition to the tail, the Si center is bonded to 2 or 3 reactive head groups, or two or more reactive head groups (e.g., —OR, Cl, and/or —NR₂ including combinations thereof). In some embodiments, such as embodiments including two reactive head groups, a remaining moiety bonded to the Si center may include a short, inert saturated hydrocarbon moiety (methyl or ethyl). In embodiments, second SMM or second SAM, in addition to the tail, the Si center may be bonded to one and only one reactive head group (e.g., —OR, —Cl, and/or —NR₂). In such embodiments, the remaining two moieties bonded to the Si center may include two short, inert saturated hydrocarbon moieties (methyl or ethyl).

In some embodiments, reactive (e.g., OH) groups on substrate surface-bound first SMM or first SAM precursor may be formed by contacting surface-bound first SMM or first SAM precursor with a co-reactant described further below, such as water. The co-reactant exposure allows for exchange between the co-reactant and the unreacted head groups of the surface-bound first SMM precursor or first SAM precursor. In some embodiments, suitable co-reactants for use herein include hydroxyl moiety precursors such as ambient air, water solution or vapor, hydrogen peroxide solution or vapor, organic alcohol solutions or vapors, such as methanol, isopropanol, ethanol, and diols, among others. Hydrogen gas and oxygen gas may also be utilized in combination to form hydroxyl moieties. It is contemplated that other non-hydroxyl moiety precursors may also be utilized in accordance with the implementations described herein. Non-hydroxyl moiety precursors may include nitrogen gas, (di)isocyanates, hydrogen sulfide, and ammonia, among others.

In some embodiments, a method of treating a substrate includes: contacting a substrate having a top surface or outer surface with a first self-assembled monolayer (SAM) precursor or a first small-molecule monolayer (SMM) precursor, a co-reactant, and a second SAM precursor or a second SMM precursor to form a first layer on the top surface or outer surface. In some embodiments, the first SAM precursor SMM precursor may be provided in a blocking cycle and be different from the second SAM or second SMM precursor in the blocking cycle. For example, and as explained above, the first SAM or first SMM precursor may include two or three reactive head groups, while the second SAM or second SMM precursor includes one reactive head group. In embodiments, a head group may be a moiety chosen to react with functionality on the surface/material on which subsequent film deposition is not desired.

In some embodiments, the substrate having a top surface is contacted with a first or second self-assembled monolayer (SAM) precursor, wherein the first self-assembled monolayer (SAM) precursor and the second SAM precursor are different such as for example in the number of reactive head groups where the first self-assembled monolayer (SAM) precursor includes two or three reactive head groups, and the second SAM or second SMM precursor includes one reactive head group. In embodiments, suitable first and second self-assembled monolayer (SAM) precursors for use herein may include an ordered arrangement of spontaneously assembled organic molecules suitable for being adsorbed on a surface of the substrate. In embodiments, first and second SAM molecules may typically include one or more moieties including reactive head groups with an affinity for the substrate (head group) and a relatively long, inert, linear hydrocarbon moiety (tail group). In some embodiments, the first and second SAM precursors include a terminal group at the end of the hydrocarbon tail including a functional group such as CH₃, COOH, or NH₂ which may be preselected to modify the top surface of a layer. In some embodiments, suitable first and second SAM precursors for use in accordance with the present disclosure include one or more chlorosilane and/or silylamine-based molecules including a linear, saturated hydrocarbon tail of 6-20 carbons and two or more (several) head groups including a silicon center, and at least one —Cl, —OR, —NR₂ (or combinations thereof) on a silicon center, wherein each R is independently methyl or ethyl.

Non-limiting examples of suitable silylamine materials suitable for use herein include tris(dimethylamino)methylsilane, tris(dimethylamino)ethylsilane, tris(dimethylamino)propylsilane, tris(dimethylamino)butylsilane, tris(dimethylamino)pentylsilane, tris(dimethylamino)hexylsilane, tris(dimethylamino)heptylsilane, tris(dimethylamino)octylsilane, tris(dimethylamino)nonylsilane, tris(dimethylamino)decylsilane, tris(dimethylamino)undecylsilane tris(dimethylamino)dodecylsilane, tris(dimethylamino)tridecylsilane, tris(dimethylamino)tetradecylsilane, tris(dimethylamino)pentadecylsilane, tris(dimethylamino)hexadecylsilane, tris(dimethylamino)heptadecylsilane, tris(dimethylamino)octadecylsilane, tris(dimethylamino)nonadecylsilane, and combinations thereof. In embodiments, silyamine materials are preselected depending upon the number of reactive head groups, the length of the alkyl tail group, and/or order of sequential application of the silyamine material(s) to the substrate as described herein.

In some embodiments, the SAM molecules or precursors may be chlorosilane materials. Non-limiting examples of chlorosilane materials suitable for use herein include methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane, nonadecyltrichlorosilane, and combinations thereof. In embodiments, chlorosilane materials are preselected depending upon the number of reactive head groups, the length of the alkyl tail group, and/or order of sequential application of the chlorosilane material(s) to the substrate as described herein.

Non-limiting examples of suitable chlorosilane materials suitable for use herein including two or more (several) head groups comprising a three reactive demethylamine head groups, and may in embodiments, comprise a tail having carbons having a length of C1 to C9. Other non-limiting examples of suitable chlorosilane materials suitable for use herein including one or two head groups comprising one or two reactive demethylamine head groups. In embodiments, each head group may comprise terminations selected from the group consisting of diethylamino, ethylmethyl, or the like. In embodiments, SAM molecules are preselected to comprise 1, 2 and 3 Cl head groups such as a head group comprising chlorine.

In some embodiments, the first SAM precursors include a terminal group at the end of the hydrocarbon tail including a two or more functional groups such as CH₃, OH, COOH, or NH₂ which may be preselected to modify the top surface of the layer. In some embodiments, the first SAM precursors include a terminal group at the end of the hydrocarbon tail including a two or more functional groups such as methyl group, hydroxyl group, carboxyl group, or amine group which may be preselected to modify the top surface of the layer. In some embodiments, the second SAM precursor is preselected to have only one reactive head group or functional group.

In some embodiments, first SAM precursor(s) may be preselected such that the head group selectively reacts with Si-based dielectrics or dielectric functional groups thereon. For example, wherein the top surface of the substrate includes H-terminated SiₓGe₁₋ₓ, a metal, or a metal oxide, and a second surface of the substrate includes hydroxyl-terminations on a Si-containing dielectric, SAM precursor may be preselected to include one or more chlorosilane and/or silylamine-based molecules including a linear, saturated hydrocarbon tail of 6-20 carbons and two or more heads comprising a silicon center, and at least one —Cl, —OR, or —NR₂ on a silicon center, wherein each R is independently methyl or ethyl.

In some embodiments, the second SAM or second SMM precursor is preselected to react with any exchanged reactive groups (e.g., OH) of a first SAM precursor or first SMM precursor that is disposed upon the substrate. In embodiments, the second SAM precursor or second SMM precursor is preselected to cap or eliminate any unreacted reactive groups on the first SAM precursor or first SMM precursor.

In embodiments, the flow rates of the first or second SAM precursor may be greater than or about 100 sccm, greater than or about 150 sccm, or greater than or about 250 sccm. In embodiments, first SAM precursor such as n-octadecyltris(dimethylamino) silane may be mixed with additional gases that may act as carrier gases, reactive gases, or both. Additional gases may include H₂, N₂, NH₃, He, Ne and/or Ar, among other gases.

In embodiments, the substrate having a top surface is contacted with a first small-molecule monolayer (SMM) precursor or a first or second SMM precursor. In embodiments, suitable first and second small-molecule monolayer (SMM) precursors for use in accordance with the present disclosure may include one or more analogues to the first and second SAM precursors described above, but without the tail group or terminal group as described above. In embodiments, suitable first and second SMM precursors may include one or more moieties with an affinity for the substrate with the remaining moieties being substantially inert (for the process range of interest) with respect to reaction with the substrate or ALD precursors to which the functionalized substrate may subsequently be exposed. In some embodiments, the SMM precursor may have the same number and type of reactive moieties or functional groups as a similar SAM precursor analogue. In embodiments, inert moieties on the SMM precursor may be hydrocarbon moieties including less than three carbons.

In some embodiments, the first SMM precursor and the second SMM precursor are different SMM molecules. For example the first SMM precursor may be preselected to include two or more (several) reactive head groups as described above which may be preselected to modify the top surface of the substrate. In some embodiments, the second SMM precursor is preselected to react with any exchanged reactive groups (e.g., OH) of a first SMM precursor that is disposed upon the substrate. In embodiments, the second SMM precursor is preselected to cap or eliminate any unreacted reactive groups on the first SAM precursor or first SMM precursor.

In embodiments, the flow rates of the first or second SMM precursor may be greater than or about 100 sccm, greater than or about 150 sccm, or greater than or about 250 sccm. In embodiments, the first and/or second SMM precursors such as silyl-amines may be mixed with additional gases that may act as carrier gases, reactive gases, or both. Additional gases may include H₂, N₂, NH₃, He, Ne and/or Ar, among other gases.

In embodiments, the substrate having a top surface may be contacted with a co-reactant. For example, some embodiments of the present disclosure advantageously modify a SAM precursor or the first SMM precursor by contacting the SAM precursor or the first SMM precursor with one or more co-reactants to maintain an all-vapor nature of the overall process while increasing the first SAM or first SMM surface coverage on the materials to be layered or blocked, thus increasing blocking capability and selective deposition margin. In some embodiments, the co-reactant is applied to the substrate separately, or following the application of a first self-assembled monolayer (SAM) precursor or a first small-molecule monolayer (SMM). In embodiments, the co-reactant may be a molecule that undergoes ligand exchange with unreacted head groups or functional groups on a first SAM precursor or first SMM precursor. In embodiments, the co-reactant is chosen such that the co-reactant does not chemisorb on any substrate materials at or below the substrate temperature used for the first SAM precursor or first SMM exposure. In some embodiments, introducing the co-reactant into the process is by alternate exposure (spatially or temporally) with the first SAM precursor or first SMM precursor to reduce the potential for particle formation and/or drive ligand exchange with unreacted head groups on a chemisorbed SAM precursor or chemisorbed SMM precursor. In embodiments, the first SAM precursor or first SMM precursor have two or three reactant head group for use with the co-reactant such as two or more several reactive head groups. Following a ligand exchange, neighboring chemisorbed SAM precursors or SMM precursors may react with each other via a condensation reaction (through the exchanged ligands) that yields crosslinking between chemisorbed first SAM or first SMM molecules and a volatile byproduct that does not decompose or react with any substrate materials under the treatment conditions. Crosslinking may promote tail alignment of chemisorbed SAM molecules, thus allowing for further chemisorption of SAM precursor during a subsequent second SAM or second SMM precursor exposure. Non-limiting examples of co-reactant include alcohol, methanol, ethanol, water, hydroxyl moiety precursors described above, or combinations thereof. In some embodiments, a first self-assembled monolayer (SAM) precursor or a first small-molecule monolayer (SMM), a co-reactant, and a second SAM or second SMM precursor are sequentially exposed to the substrate. The second SMM precursor is different than the first small-molecule precursor or first SMM precursor as described above. In embodiments, the second SAM precursor or second SMM precursor is applied to the substrate under the same or similar conditions as the first SMM precursor or first SAM precursor as described above.

In embodiments a first SAM precursor or first SMM precursor may include 2 or three (several) reactive groups for attaching to the surface of a substrate. Subsequently, a co-reactant exchanges with any unconsumed reactive groups on the deposited first SAM precursor or first SMM precursor. Next, the second SMM or second SAM precursor including only one reactive head group reacts with any exchanged reactive groups (e.g., OH) of the attached first SAM or first SMM precursor molecules to cap or eliminate any reactive sites.

In embodiments, the SAM precursor or first SMM precursor, co-reactant, and second SMM precursor or second SMM precursor may be introduced to a reaction chambers in vapor phase through one or more lines. For SAM precursor (first or second) SMM precursor (first or second) and co-reactant exposures, soak or flow conditions may be used (with or without the assistance of an inert gas, with exposure times that vary from seconds to days, substrate temperatures that range from room temperature to approximately 600° C. In some embodiments, the substrate temperature can be in the range of about room temperature (e.g., 25° C.) to about 500° C., or in the range of about room temperature to about 400° C., 350° C., 300° C., 250° C. or 200° C., and chamber/dose pressures up to approximately 760 Torr. These conditions can be applied to a range of first or second SAM precursor head group moieties and tail lengths, co-reactant functional groups, and first or second SMM precursors, and substrate materials used in the semiconductor industry.

In some embodiments, a method of treating a substrate includes: contacting a substrate having a top surface with a first self-assembled monolayer (SAM) precursor, a co-reactant, and a second SAM precursor to form a first layer on the top surface. For example, a first self-assembled monolayer (SAM) precursor such as n-octadecyltris (dimethylamino)silane, a co-reactant such as water, and a second SAM precursor such as n-octadecyl (dimethylamino)dimethylsilane may be contacted to form a first layer on the top surface The second SAM precursor is different from the first SAM precursor to cap or eliminate unreacted functional groups in the first self-assembled monolayer (SAM) precursor adsorbed to the top surface of the substrate or another layer. In embodiments, the first SAM precursor, co-reactant, and second SAM precursor may be introduced to a reaction chambers in vapor phase through one or more lines. For first SAM precursor, co-reactant, and second SAM precursor exposures, soak or flow conditions may be used (with or without the assistance of an inert gas, with exposure times that vary from seconds to days, substrate temperatures that range from room temperature to approximately 600° C. In some embodiments, the substrate temperature can be in the range of about room temperature (e.g., 25° C.) to about 500° C., or in the range of about room temperature to about 400° C., 350° C., 300° C., 250° C. or 200° C., and chamber/dose pressures up to approximately 760 Torr. These conditions can be applied to a range of first or second SAM precursor head group moieties and tail lengths, co-reactant functional groups, and substrate materials used in the semiconductor industry.

In some embodiments, a method of treating a substrate includes: contacting a substrate having a top surface with a first self-assembled monolayer (SAM) precursor such as n-octadecyltris(dimethylamino)silane, a co-reactant such as water, and a second SMM precursor such as dimethylaminotrimethylsilane to form a first layer on the top surface. The second SMM precursor such as dimethylaminotrimethylsilane may be preselected to have one reactive head group to cap or eliminate unreacted functional groups in the first self-assembled monolayer (SAM) precursor such as n-octadecyltris(dimethylamino)silane adsorbed to the top surface of the substrate or another layer. In embodiments, the first SAM precursor, co-reactant, and second SMM precursor may be introduced to a reaction chambers in vapor phase through one or more lines. For first SAM precursor, co-reactant, and second SMM precursor exposures, soak or flow conditions may be used (with or without the assistance of an inert gas, with exposure times that vary from seconds to days, substrate temperatures that range from room temperature to approximately 600° C. In some embodiments, the substrate temperature can be in the range of about room temperature (e.g., 25° C.) to about 500° C., or in the range of about room temperature to about 400° C., 350° C., 300° C., 250° C. or 200° C., and chamber/dose pressures up to approximately 760 Torr. These conditions can be applied to a range of first or second SMM precursor head group moieties and tail lengths, co-reactant functional groups, and substrate materials used in the semiconductor industry.

In some embodiments, a method of treating a substrate includes: contacting a substrate having a top surface with a first SMM precursor such as bis (dimethylaminodimethylsilane, a co-reactant such as water, and a second SAM precursor such as n-octadecyl (dimethylamino)dimethylsilane to form a first layer on the top surface. The second SAM precursor may be different from the first SMM precursor to cap or eliminate unreacted functional groups in the first SMM precursor adsorbed to the top surface of the substrate or another layer. In embodiments, the first SMM precursor, co-reactant, and second SAM precursor may be introduced to a reaction chambers in vapor phase through one or more lines. For first SMM precursor, co-reactant, and second SAM precursor exposures, soak or flow conditions may be used (with or without the assistance of an inert gas, with exposure times that vary from seconds to days, substrate temperatures that range from room temperature to approximately 600° C. In some embodiments, the substrate temperature can be in the range of about room temperature (e.g., 25° C.) to about 500° C., or in the range of about room temperature to about 400° C., 350° C., 300° C., 250° C. or 200° C., and chamber/dose pressures up to approximately 760 Torr. These conditions can be applied to a range of first SMM precursor or second SAM precursor head group moieties and tail lengths, co-reactant functional groups, and substrate materials used in the semiconductor industry.

In some embodiments, a method of treating a substrate includes: contacting a substrate having a top surface with a first SMM precursor such as bis (dimethylamino)dimethylsilane, a co-reactant such as water, and a second SMM precursor such as dimethylaminotrimethylsilane to form a first layer on the top surface. The second SMM precursor may be different from the first SMM precursor to cap or eliminate unreacted functional groups in the first SMM precursor adsorbed to the top surface of the substrate or another layer. In embodiments, the first SMM precursor, co-reactant, and second SMM precursor may be introduced to a reaction chambers in vapor phase through one or more lines. For first SMM precursor, co-reactant, and second SMM precursor exposures, soak or flow conditions may be used (with or without the assistance of an inert gas, with exposure times that vary from seconds to days, substrate temperatures that range from room temperature to approximately 600° C. In some embodiments, the substrate temperature can be in the range of about room temperature (e.g., 25° C.) to about 500° C., or in the range of about room temperature to about 400° C., 350° C., 300° C., 250° C. or 200° C., and chamber/dose pressures up to approximately 760 Torr. These conditions can be applied to a range of first or second SMM precursors, co-reactant functional groups, and substrate materials used in the semiconductor industry.

In some embodiments, a selective deposition method includes: contacting a substrate with a first surface and a second surface with a first self-assembled monolayer (SAM) precursor or a first small-molecule monolayer (SMM) precursor, a co-reactant, and a second SMM precursor or second SMM precursor to form a first layer on the second surface; depositing a film on the first surface selectively over the second surface; and removing the first layer from the second surface. In embodiments, selective deposition on metal, metal oxide, or hydrogen-terminated SiₓGe₁₋ₓ substrates and not silicon-containing dielectric substrates, which typically have a high concentration of surface Si—OH sites, may be performed. Examples of first and second SAM precursors for such an application include but are not limited to first and second SAM precursors as described above. According to some embodiments, a reaction of first and second SAM precursors with silicon-containing dielectrics yields Si—O bond formation between the SAM precursor and the substrate through reaction of surface hydroxyls with Si—Cl, Si—N, or Si—OR precursor bonds to yield alcohol byproducts, respectively. However, some head groups of the first SAM precursor or first SMM precursor may remain unreacted upon chemisorption of the first SAM precursor or first SMM precursor, so that the use of a co-reactant and a second SMM precursor or second SAM precursor may modify selectivity and/or reactivity. In some embodiments, the first SAM precursor is selected to comprise a head group comprising two or more reactive sites, and the second SAM precursor is selected to have a head group having one reactive site.

In some embodiments, a selective deposition method includes: contacting a substrate with a first surface and a second surface with a first self-assembled monolayer (SAM) precursor or a first small-molecule monolayer (SMM) precursor, a co-reactant, and a second SAM precursor or a second SMM precursor to form a first layer on the second surface; depositing a film on the first surface selectively over the second surface; and removing the first layer from the second surface. In embodiments, the first small-molecule monolayer (SMM) and the second SMM precursor are a different SMM precursor molecules and have a different number of reactive head groups as described above. In embodiments, the co-reactant is flowed separately from the first self-assembled monolayer (SAM) precursor or the first small-molecule monolayer (SMM). In embodiments, the first self-assembled monolayer (SAM) precursor or a first small-molecule monolayer (SMM), the co-reactant, and second SMM precursor or second SAM precursor are sequentially exposed to the substrate. In embodiments, the first or second SAM precursor include a composition with a head group and a tail group. In embodiments, the head group adsorbs to the second surface. In some embodiments, the head group comprises two or more functional groups for reacting with the second surface. In embodiments, the first SAM precursor includes more than two head groups and/or more than one tail group, and wherein the head groups comprises several reactive head groups. In embodiments, the first SAM precursor, second SAM precursor, first SMM precursor, or second SMM precursor, and the co-reactant are exposed to the substrate a temperature in a range of about room temperature to about 600° C. or about 250° C., for example, the substrate temperature can be in the range of about room temperature (e.g., 25° C.) to about 500° C., or in the range of about room temperature to about 400° C., 350° C., 300° C., 250° C. or 200° C., and chamber/dose pressures up to approximately 760 Torr for a duration between two seconds to two days. In embodiments, the co-reactant includes alcohol, methanol, ethanol, water, or combinations thereof.

In some embodiments, a selective deposition method includes: (a) contacting a substrate with a first surface and a second surface with a first SAM precursor or a first SMM precursor; (b) subsequently, contacting a substrate with a first surface and a second surface with a co-reactant; (c) subsequently, contacting a substrate with the first surface and the second surface with a second SMM precursor or a second SAM precursor to form a layer on the second surface; and optionally (d) repeating (a), (b) and (c) until the layer has a desired surface coverage. For example, desired surface coverage may be coverage of the second surface to maximize surface coverage of a blocking layer or cover a sufficient amount of reactive sites as described above. In some embodiments, desired surface coverage is achieved by forming a target composition such as forming a blocking layer on second surface, or a composition with a substantially low number of reactive sites, or no reactive sites in a blocking layer. In some embodiments, desired coverage includes a substrate composition having a top surface including a first surface and a second surface and the first layer is formed on the second surface in amount sufficient to block growth thereon during a subsequent film deposition.

In some embodiments, a selective deposition method includes: (a) contacting a substrate with a first surface and a second surface with a first SAM precursor, wherein the first SAM precursor has a first tail length (b) subsequently, contacting a substrate with a first surface and a second surface with a co-reactant; (c) subsequently, contacting a substrate with the first surface and the second surface with a second SAM precursor, wherein the second SAM precursor has a second tail length, to form a layer on the second surface; and optionally (d) repeating (a), (b) and (c) until the layer has a desired surface coverage, wherein the first tail length is longer than the second tail length. In embodiments, the first SAM precursor is preselected to have a tail length longer than the tail length of the second SAM precursor, subsequently contacted with the substrate. For example, in embodiments, non-limiting suitable examples of first and second SAM precursors include one or more organoaminosilanes. Non-limiting examples of suitable organoaminosilanes includes silylamine materials including those described in U.S. patent application Ser. No. 15/446,816 entitled Self-Assembled Monolayer Blocking with Intermittent Air-Water Exposure to Kaufman-Osborn et al.

Non-limiting examples of silylamine materials suitable for use as first or second SAM precursor include tris(dimethylamino)methylsilane, tris(dimethylamino)ethylsilane, tris(dimethylamino)propylsilane, tris(dimethylamino)butylsilane, tris(dimethylamino)pentylsilane, tris(dimethylamino)hexylsilane, tris(dimethylamino)heptylsilane, tris(dimethylamino)octylsilane, tris(dimethylamino)nonylsilane, tris(dimethylamino)decylsilane, tris(dimethylamino)undecylsilane tris(dimethylamino)dodecylsilane, tris(dimethylamino)tridecylsilane, tris(dimethylamino)tetradecylsilane, tris(dimethylamino)pentadecylsilane, tris(dimethylamino)hexadecylsilane, tris(dimethylamino)heptadecylsilane, tris(dimethylamino)octadecylsilane, tris(dimethylamino)nonadecylsilane, and combinations thereof.

During operation, the substrate may be sequentially exposed to a first SAM having a first tail length, followed by a second SAM having a shorter tail length. For example, the fist SAM may have an alkyl tail length of n and the second SAM may have an alkyl tail length of n minus 1 to 100, n minus 5 to 75, n minus 10 to 50, n minus 20 to 30, n minus, 1, n minus 2, n minus 3, n minus 4, n minus 5, n minus 6, n minus 7, n minus 8, n minus 9 or n minus 10, and the like. In embodiments, the first SAM to contact the substrate has a tail length more than 5%, more than 10, more than 20%, more than 30%, more than 40%, or more than 50% longer than the tail length of a second SAM contacted with the substrate subsequent to the first SAM application. In embodiments, the sequential application of a first SAM having a longer tail length than the second SAM reduces the prevalence of the first SAM sterically hindering or blocking the second SAM from reacting with reactive sites on the substrate. As a result, the combination of the first SAM precursor having a longer tail length than the second SAM precursor, applied sequentially, are able to more fully adsorb on the surface of a substrate in a closely packed orientation. For example, it is believed that sequential application of a first SAM precursor having a longer alkyl tail length followed by a second SAM precursor having a tail length shorter than the first SAM precursor promotes adsorption of SAM molecules on the surface of the substrate or facilitates formation of a densely packed SAMs which exhibits reduced or eliminated pin holes. Non-limiting examples of SAM precursors having lengthy tails include tris(dimethylamino)octadecylsilane, tris(dimethylamino)dodecylsilane, and dodecyl-dimethyl(dimethylamino)silane. Non-limiting examples of SAMS having shorter tails compared to SAM precursors having lengthy tails include: dimethylaminotrimethysilane, and chemicals with the following formulations:

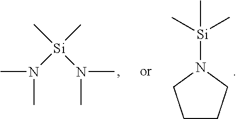

In embodiments, such as where a first SAM is preselected to have a longer tail than a subsequently applied second SAM, suitable reaction conditions for contacting the SAM with the substrate include:

### First SAM Dosing:

Pressure in the range of 0.5 Torr to 500 Torr
Temperature in the range of 25° C. to 250° C.
Duration of 5 seconds to 4 hours

### Co-Reactant Dosing:

Pressure in the range of 0.5 Torr to 500 Torr
Temperature in the range of 25° C. to 250° C.
Duration of 5 seconds to 2 hours

### Second SAM Dosing

Pressure in the range of 0.5 Torr to 500 Torr
Temperature in the range of 25° C. to 250° C.
Duration of 5 seconds to 4 hours
   The application of the first and second SAM precursor or molecule may be cycled, e.g. 30 to 75 times, or a number of cycles sufficient obtain desired surface coverage of the substrate, or desired portion thereof. In some embodiments, 3 type dosing is performed to form a dense SAM blocking layer, which selectively binds to a preselected substrate surface.

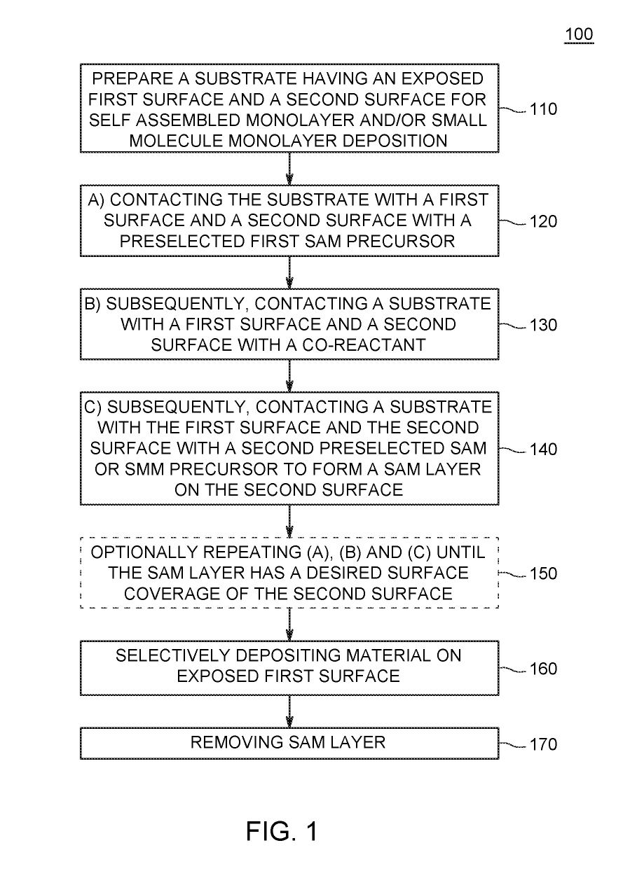

Referring now to FIG. 1, one embodiment of a selective deposition method 100 in accordance with the present disclosure is shown. In embodiments, at 110, a substrate having an exposed first surface and a second surface for self-assembled monolayer and/or small molecule monolayer deposition is prepared. Suitable preparation of the substrate may include, selecting a first material and a second material as described above, pre-treatment as described above, pre-cleaning the substrate prior to the SAM layer or film formation process, and combinations of these. The pre-clean process may be any pre-clean process capable of removing native oxides, contaminants, or both from the exposed surfaces.

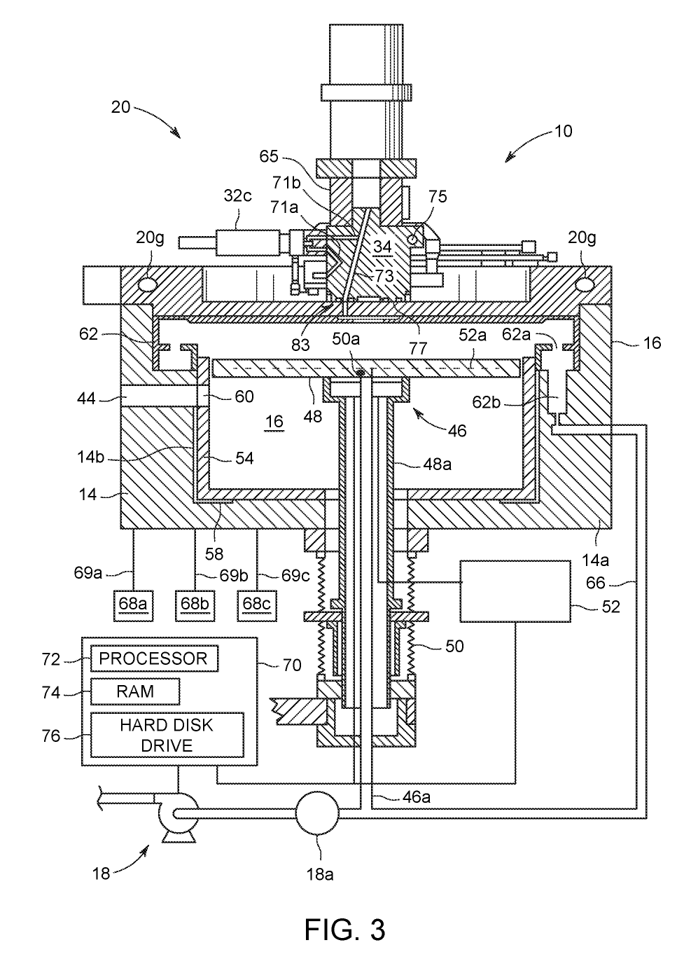

Subsequent to preparing the substrate, the substrate with a first surface and a second surface is contacted or exposed at 120 to a preselected first SAM precursor. In embodiments, the preselected first SAM precursor may be any first SAM precursor described above or a small molecule monolayer precursor. In embodiments, a SAM or SMM molecule is preselected to achieve selective adsorption of the SAM or SMM molecule on a first material or a first or a second surface of the substrate including the first material. The SAM or SMM molecule(s) are applied under conditions described above and in an amount sufficient to form a SAM layer atop the substrate. In one implementation, the SAM adsorption may be a vapor phase deposition process. In this implementation, SAM molecules may be vaporized in an ampoule maintained at a temperature between about 25° C. and about 300° C., such as between about 125° C. and about 200° C. The substrate may be maintained at a temperature of between about 25° C. and about 400° C., such as between about 50° C. and about 200° C., for example, between about 100° C. and about 175° C. A pressure of the substrate processing environment, such as the processing volume of a processing chamber such as process chamber 16 in FIG. 3, may be maintained at a pressure of between about 1 mTorr and about 1520 Torr, such as between about 5 Torr and about 600 Torr. A carrier gas may be utilized to facilitate delivery of vapor phase SAM molecules and the carrier gas, depending on the volume of the processing chamber, may be delivered at a flow rate of between about 25 sccm and about 3000 sccm, such as between about 50 sccm and about 1000 sccm. Suitable carrier gases include gases, such as noble gases or the like, that are generally inert under SAM or SMM adsorption conditions that facilitate delivery of the SAM molecules to the substrate surfaces. The SAM molecules may be exposed to the substrate in operation 120 for an amount of time between about 1 second and about 48 hours, for example, between about 1 minute and about 120 minutes.

Subsequent to the initial SAM or SMM contact with the substrate, the SAM or SMM layer may be contacted (such as in process chamber 16) with and/or exposed to a co-reactant as described above as shown at 130. In embodiments, the co-reactant is water, or ambient air, or water vapor. In embodiments, co-reactant is applied while the temperature of the substrate may be maintained at a temperature of between about 25° C. and about 400° C. in a processing environment having a pressure of between about 1 mTorr and about 1520 Torr. In some embodiments, the substrate may be exposed to ambient air for an amount of time between about 30 seconds and about 600 seconds. In some embodiments, the ambient air exposure may be performed in a vacuum chamber pumped up to atmospheric pressure or the substrate may be removed from a vacuum processing chamber environment and maintained in ambient air at approximately atmospheric pressure. In embodiments where the co-reactant is water vapor, a temperature of the substrate may be maintained between about 20° C. and about 400° C. and a pressure of the processing environment may be maintained between about 2 Torr and about 1520 Torr.

In embodiments, the contact or exposure to a co-reactant 130 may be performed in the same processing environment as the exposure of the substrate to the first SAM or first SMM molecule at 120. Alternatively, the exposure to a co-reactant may be performed in a processing environment different than the processing environment utilized to expose the substrate to the first SAM or SMM molecule.

At operation 140, the operation includes subsequently, contacting a substrate with the first surface and the second surface with a second preselected SAM or SMM precursor to form a SAM layer on the second surface. In embodiments, the conditions of operation 140 may be the same as the conditions set forth with respect to operation 120.

At operation 150, operation 120 operation 130, and operation 140 may be optionally repeated in a sequential or simultaneous manner. For example, operation 120, operation 130 and operation 140 may be repeated between about 1 time and about 500 times. In one implementation, operation 120 may be performed a first time, operation 130 may be performed a first time, and operation 140 may be performed a first time, and operation 120 may be performed a second time. In this implementation, the operations may be performed sequentially. In another implementation, operation 120, operation 130 and operation 140 may be repeated between about 5 times and about 50 times. In another implementation, operation 120, operation 130 and operation 140 may be repeated between about 30 times and about 75 times. In this implementation, operation 150 may be followed by an additional operation 120 such that exposure of the substrate to the SAM or SMM molecule is performed immediately prior to operation 150. In embodiments, the alternating SAM or SMM molecules may be preselected as described in the various embodiments above.

At operation 160, a deposition process, which is a process highly sensitive to surface conditions, having selected precursors, is then performed to form a structure selectively on a surface of the first or second material. The structure may be formed by various techniques including, for example, chemical vapor deposition (CVD), such as plasma-enhanced CVD (PE-CVD), pulsed-CVD, low pressure CVD (LPCVD), epitaxial growth, physical vapor deposition (PVD) such as sputtering or evaporation, atomic layer deposition (ALD), electroplating, other techniques, or combinations thereof. The material selected to be deposited may be influenced by the surface properties of the substrate. The thickness of the structure will vary depending on the materials and particular devices being formed. The SAM layer prevents deposition of the material on the surface of the first or second material according to design. In this manner, a selective deposition process may selectively deposit different materials at different locations on the substrate.

In one implementation, the deposition process is an ALD process. As the ALD process is sensitive to surface conditions, ALD is suitable for a selective deposition of materials on specific regions of the substrate. The ALD process is a CVD process with self-terminating/limiting growth. The ALD process yields a thickness of only a few angstroms or in a monolayer level. The ALD process is controlled by distribution of a chemical reaction into two separate half reactions which are repeated in cycles. The thickness of the material formed by the ALD process depends on the number of the reaction cycles. The first reaction provides a first atomic layer of molecular layer being absorbed on the substrate and the second reaction provides a second atomic layer of molecular layer being absorbed on the first atomic layer. As such, the ordered structure of the material acts as a template for the growth of the material layer.

Following the deposition process of operation 160, at operation 170, the SAM layer is removed from the surface of the first or second material (depending upon where deposited). The SAM layer may be removed by any process which does not adversely affect structure or the surface of the remaining or desired material. In embodiments, the process for removing the SAM layer is the result of the selection of the terminal and head groups of the SAM molecules. The SAM layer may be removed by a wet etching process, a dry etching process, a high temperature anneal process (e.g., greater than 300° C.) to release the SAM layer from the surface the material to which it chemically bonded. Subsequent to operation 160, additional processing operations may be performed to manufacture semiconductor and other device features.

In some embodiments, a method of treating a substrate includes: (a) contacting a substrate having a top surface or outer surface with a first small-molecule monolayer (SMM) precursor; and (b) contacting the first small-molecule monolayer (SMM) precursor with a co-reactant, and repeating (a), (b) until a layer having a desired surface coverage is formed thereon. In one such embodiment, the first small-molecule monolayer (SMM) precursor has two or three (several) reactive head groups.

In embodiments, methods of the present disclosure, such as method 100, may be performed on a substrate 200 provided to a processing volume of a process chamber such as process chamber 16 shown in FIG. 3. In some embodiments, as shown in FIG. 2A, the substrate 200 may have a top surface 205 suitable for being contacted with a first self-assembled monolayer (SAM) precursor or a first small-molecule monolayer (SMM) precursor, a co-reactant, and a second SAM precursor or a second SMM precursor to form a first layer 207 on the top surface 205. In embodiments, first layer 207 covers the entire top surface 205, or a portion of top surface 205 depending upon design needs. Although this description is made with respect to a substantially planar substrate 200 as shown in FIGS. 2A-2C, substrate 200 may optionally include one or more features (such as a plurality of trenches, vias or the like) (not shown in FIGS. 2A-2C). In some embodiments, the substrate 200 may be any suitable substrate as described above.

Referring to FIG. 2B, in some embodiments, substrate 200 is suitable for selective deposition in accordance with the present disclosure and includes a first surface 211 and a second surface 212. In embodiments, first surface 211 and second surface 212 have an equivalent height to one another and form the top field of the substrate 200. In embodiments, as shown in FIG. 2B, the first surface 211 and second surface 212 are distinct layers, each disposed directly atop the top surface 205. In embodiments, substrate 200 is configured for a selective deposition method wherein the first surface 211 and a second surface 212 are exposed to and suitable for contact with precursor described above, such as a preselected first SAM precursor. In embodiments, substrate 200 is configured for a selective deposition method wherein first surface 211 and second surface 212 are exposed to contact with a co-reactant as described herein. In embodiments, the substrate 200 with the first surface 211 and the second surface 212 is configured such that a second preselected SAM precursor may form a SAM layer 215 on the second surface 212. In embodiments, these process sequences may be repeated until the SAM layer 215 has a desired surface coverage of the second surface 212. In embodiments, a first SAM precursor and second preselected SAM precursor together form a SAM layer 215 on the second surface. In embodiments, although not shown in FIGS. 2A-2C, additional materials can be deposited atop an exposed first surface 216 of the first surface 211 and/or atop the exposed first surface 216 and SAM layer 215, forming additional one or more layers or films thereon. In embodiments, the SAM layer 215 (and any materials deposited thereon) may be removed, leaving only material deposited upon exposed first surface 216.

Referring to FIG. 2B, in some embodiments, the top surface 205 comprises a first surface 211 and a second surface 212 and the first layer such as SAM layer 215 may be formed on the second surface 212 in amount sufficient to block growth thereon during a subsequent film deposition. In embodiments, the amount sufficient may be a thickness sufficient to prevent further deposited material from contacting or reacting with the second surface 212. Some embodiments further comprise depositing a film on the first surface 211 selectively over the second surface 212. Some embodiments further include removing the first layer such as SAM layer 215 from the second surface 212.

Referring to FIG. 3, a process chamber 16 suitable for precursor deposition and selective deposition in accordance with the present disclosure is shown. In embodiments, process chamber 16 may be configured to operate in both CVD mode and a cyclical deposition mode (ALD). Referring to FIG. 3, disposed within process chamber 16 is a heater/lift assembly 46 that includes a support pedestal 48 connected to a support shaft 48a suitable for supporting a wafer. The support pedestal 48 is positioned between the support shaft 48a and the lid assembly 20 when the lid assembly 20 is in the closed position. The support shaft 48a extends from the support pedestal 48 away from lid assembly 20 through a passage formed in the housing 14. A bellows 50 is attached to a portion of the housing 14 disposed opposite to the lid assembly 20 to prevent leakage into the process chamber 16 from between the support shaft 48a and housing 14. The heater/lift assembly 46 may be moved vertically within the process chamber 16 so that a distance between support pedestal 48 and lid assembly 20 may be controlled. A sensor (not shown) provides information concerning the position of support pedestal 48 within process chamber 16.

The support pedestal 48 includes an embedded thermocouple 50a that may be used to monitor the temperature thereof. For example, a signal from the thermocouple 50a may be used in a feedback loop to control power applied to a heater element 52a by a power source 52. The heater element 52a may be a resistive heater element or other thermal transfer device disposed in or in contact with the support pedestal 48 utilized to control the temperature thereof. Optionally, support pedestal 48 may be heated using a heat transfer fluid (not shown).

The support pedestal 48 may be formed from any process-compatible material, including aluminum nitride and aluminum oxide and may also be configured to hold a substrate 200 (not shown) thereon employing a vacuum, i.e. support pedestal 48 may be a vacuum chuck. To that end, support pedestal 48 may include a plurality of vacuum holes (not shown) that are placed in fluid communication with a vacuum source, such as pump system via vacuum tube routed through the support shaft 48a.

A liner assembly is disposed in the process chamber 16 and includes a cylindrical portion 54 and a planar portion. The cylindrical portion 54 and the planar portion may be formed from any suitable material such as aluminum, ceramic and the like. The cylindrical portion 54 surrounds the support pedestal 48. The cylindrical portion 54 additionally includes an aperture 60 that aligns with the slit valve opening 44 disposed a side wall 14b of the housing 14 to allow entry and egress of substrates from the process chamber 16.

Disposed along the side walls 14b of the process chamber 16 proximate the lid assembly 20 is a pumping channel 62. The pumping channel 62 includes a plurality of apertures, one of which is shown as a first aperture 62a. The pumping channel 62 includes a second aperture 62b that is coupled to a pump system 18 by a conduit 66. A throttle valve 18A is coupled between the pumping channel 62 and the pump system 18. The pumping channel 62, throttle valve 18A and pump system 18 control the amount of flow from the process chamber 16. The size and number and position of apertures such as first aperture 62a in communication with the process chamber 16 are configured to achieve uniform flow of gases exiting the lid assembly 20 over support pedestal 48 and substrate 200 when seated thereon. A plurality of supplies 68a, 68b and 68c of process and/or other fluids, are in fluid communication with one of valves 32a, 32b or 32c through a sequence of conduits (not shown) formed through the housing 14, lid assembly 20, and gas manifold 34.

A controller 70 regulates the operations of the various components of system 10. The controller 70 includes a processor 72 in data communication with memory, such as random access memory 74 and a hard disk drive 76 and is in communication with at least the pump system 18, the power source 52, and valves 32a, 32b and 32c.

Although any type of process fluid may be employed, one example of process fluids are precursors and co-reactants as described above, and optionally a purge fluid. The chamber pressure may be in the pressure range as described above, and the support pedestal 48 is heated such that the substrate may be maintained at a set temperature, such as the substrate at a temperature described above. In embodiments, the process fluids such as precursors may be flowed into the process chamber 16 with a carrier fluid, such as Ar. However, the purge fluid might differ from the carrier fluid or precursors, or co-reactants.

In vapor deposition embodiments in accordance with the present disclosure, the methods include performing a chemical vapor deposition (CVD) process to expose the substrate having a top surface to a first self-assembled monolayer (SAM) precursor or a first small-molecule monolayer (SMM) precursor, a co-reactant, and a second SAM precursor or a second SMM precursor to form a first layer on the top surface. In some embodiments, a chemical vapor deposition (CVD) process to expose the substrate with a first surface and a second surface with a preselected first SAM precursor; subsequently, contacting a substrate with a first surface and a second surface with a co-reactant; (c) subsequently, contacting a substrate with the first surface and the second surface with a second preselected SAM precursor to form a SAM layer on the second surface; and optionally (d) repeating (a), (b) and (c) until the SAM layer has a desired surface coverage of the second surface.

In embodiments, (SAM) precursor or a first small-molecule monolayer (SMM) precursor, and a co-reactant, are simultaneously co-flowed into process chamber 16 including a substrate. After one cycle of CVD, the process chamber 16 may be purged, evacuating the process chamber 16 of volatile reactants or unreacted precursors. In some embodiments, a purge fluid such as Argon may be added to the process chamber 16. Next, embodiments of the present disclosure perform cyclic deposition processed until coverage is sufficient to block the desired surface or area. In some embodiments, purge gases may be strategically delivered through the lower portion of the passage 73, sweeping off cleaning agents from the gas manifold 34 and baffle plate.

In another embodiment, a non-transitory computer readable medium having instructions stored thereon that, when executed, cause a deposition method such as e.g., a selective deposition method in accordance with the present disclosure. For example, in embodiments, a non-transitory computer readable medium having instructions stored thereon that, when executed, cause a selective deposition method, within or processed through a deposition chamber, including: (a) contacting a substrate with a first surface and a second surface with a preselected first SAM precursor; (b) subsequently, contacting a substrate with a first surface and a second surface with a co-reactant; (c) subsequently, contacting a substrate with the first surface and the second surface with a second preselected SAM precursor to form a SAM layer on the second surface; and optionally (d) repeating (a), (b) and (c) until the SAM layer has a desired surface coverage of the second surface.

In embodiments, a non-transitory computer readable medium having instructions stored thereon that, when executed, cause a deposition method, within or processed through a deposition chamber, including: contacting a substrate having a top surface with a first self-assembled monolayer (SAM) precursor or a first small-molecule monolayer (SMM) precursor, a co-reactant, and a second SAM precursor or a second SMM precursor to form a first layer on the top surface.

While the foregoing is directed to embodiments of the present disclosure, other and further embodiments of the disclosure may be devised without departing from the basic scope thereof.

1. A method of treating a substrate comprising:
contacting a substrate having a top surface with a first self-assembled monolayer (SAM) precursor or a first small-molecule monolayer (SMM) precursor, a co-reactant, and a second SAM precursor or a second SMM precursor to form a first layer on the top surface.

2. The method of claim 1, wherein the first small-molecule monolayer (SMM) precursor and the second SMM precursor are different, wherein the first SMM has two or more reactive head groups, and wherein the second SMM precursor has one reactive head group.

3. The method of claim 1, wherein the first self-assembled monolayer (SAM) precursor and the second SAM precursor are different, wherein the first SAM precursor has two or more reactive head groups, and wherein the second SAM precursor has one reactive head group.

4. The method of claim 1, wherein the first self-assembled monolayer (SAM) precursor or a first small-molecule monolayer (SMM), the co-reactant, and second SMM precursor or second SAM precursor are sequentially exposed to the substrate.

5. The method of claim 1, wherein the top surface comprises a first surface and a second surface and the first layer is formed on the second surface in amount sufficient to block growth thereon during a subsequent film deposition.

6. The method of claim 5, further comprising depositing a film on the first surface selectively over the second surface.

7. The method of claim 6, further comprising removing the first layer from the second surface.

8. A selective deposition method comprising:
contacting a substrate with a first surface and a second surface with a first self-assembled monolayer (SAM) precursor or a first small-molecule monolayer (SMM) precursor, a co-reactant, and a second SAM precursor or a second SMM precursor to form a first layer on the second surface; depositing a film on the first surface selectively over the second surface; and removing the first layer from the second surface.

9. The method of claim 8, wherein the first small-molecule monolayer (SMM) and the second SMM precursor are a different SMM precursor, or wherein the first self-assembled monolayer (SAM) precursor and second SAM precursor are different.

10. The method of claim 8, comprising flowing the co-reactant separately from the first self-assembled monolayer (SAM) precursor or the first small-molecule monolayer (SMM).

11. The method of claim 8, wherein the first self-assembled monolayer (SAM) precursor or a first small-molecule monolayer (SMM), the co-reactant, and second SMM precursor or second SAM precursor are sequentially exposed to the substrate.

12. The method of claim 8, wherein the first or second SAM precursor comprises a composition with a head group and a tail group, wherein the head group adsorbs to the second surface, and wherein the head group comprises one or more functional groups for reacting with the second surface.

13. The method of claim 8, wherein the first SAM precursor comprises more than one reactive head group and one or more tail groups, and wherein the reactive head groups comprises several reactive head groups.

14. The method of claim 8, wherein the first SAM precursor, second SAM precursor, first SMM precursor, or second SMM precursor, and the co-reactant are exposed to the substrate a temperature in a range of about room temperature to about 250° C., a pressure up to about 760 Torr, for a duration between two seconds to two days.

15. The method of claim 8, wherein the co-reactant comprises alcohol, methanol, ethanol, water, or combinations thereof.

16. The method of claim 8, wherein the first surface comprises H-terminated SiₓGe₁₋ₓ—, a metal, or a metal oxide, and the second surface comprises hydroxyl-terminations on a Si-containing dielectric.

17. The method of claim 8, wherein the first SAM precursor comprises one or more chlorosilane and/or silylamine-based molecules comprising a linear, saturated hydrocarbon tail of greater than 3 carbons and two or more heads comprising a silicon center, and at least one —Cl, —NR₂, —OR, or combinations thereof on a silicon center, wherein each R is independently methyl or ethyl.

18. The method of claim 8, wherein the first SAM precursor is preselected to comprise a tail group having a first length, and the second SAM precursor is preselected to have a tail group having a second length, wherein the first length is longer than the second length.

19. The method of claim 8, wherein the first SAM precursor is selected to comprise a head group comprising two or more reactive sites, and the second SAM precursor is selected to have a head group having one reactive site.

20. A non-transitory computer readable medium having instructions stored thereon that, when executed, cause a method of treating a substrate in a process chamber, comprising: contacting a substrate having a top surface with a first self-assembled monolayer (SAM) precursor or a first small-molecule monolayer (SMM) precursor, a co-reactant, and a second SAM precursor or a second SMM precursor to form a first layer on the top surface.
